(19) United States
(12) Patent Application Publication
(10) Pub. No.: US 2026/0143711 A1
(43) Pub. Date: May 21, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventors: Sang Heon LEE, Icheon-si Gyeonggi-do (KR); Hyung Jun YANG, Icheon-si Gyeonggi-do (KR)

(73) Assignee: SK hynix Inc., Icheon-si Gyeonggi-do (KR)

(21) Appl. No.: 19/097,497

(22) Filed: Apr. 1, 2025

(30) Foreign Application Priority Data
Nov. 21, 2024 (KR) 10-2024-0167429

(51) Int. Cl. H10B 43/35; H10B 43/27

(52) U.S. Cl. CPC H10B 43/35; H10B 43/27

(57) ABSTRACT

A memory device according to an embodiment of the present disclosure includes a stack structure including conductive layers and interlayer insulating layers, a channel layer penetrating the stack structure, a channel back gate layer surrounded by the channel layer, and a liner layer insulating the channel layer and the channel back gate layer from each other, wherein the channel layer is included in a first current path and the channel back gate layer is included in a second current path.

### CROSS-REFERENCE TO RELATED APPLICATION

The present application claims priority under 35 U.S.C. § 119(a) to Korean patent application number 10-2024-0167429 filed on Nov. 21, 2024, in the Korean Intellectual Property Office, the entire contents of which application is incorporated herein by reference.

### BACKGROUND

### 1. Technical Field

Various embodiments of the present disclosure generally relate to a manufacturing method of a memory device, more particularly, to a method of manufacturing a memory device including a three-dimensional memory block.

### 2. Related Art

Memory devices may include non-volatile memory devices that retain stored data even in the absence of power supply. The non-volatile memory devices may be divided into two-dimensionally structured memory devices or three-dimensionally structured memory devices, depending on arrangements of memory cells of each of the non-volatile memory devices. Memory cells of a non-volatile memory device having a two-dimensional structure may be arranged in a single layer on a substrate. Memory cells of a non-volatile memory device having a three-dimensional structure may be stacked in a vertical direction to the substrate. Because integration density of the non-volatile memory device having the three-dimensional structure is greater than that of the non-volatile memory device having the two-dimensional structure, electronic devices including three-dimensionally structured non-volatile memory devices have recently been increasing.

### SUMMARY

According to an embodiment, a memory device may include a stack structure including conductive layers and interlayer insulating layers, a channel layer penetrating the stack structure, a channel back gate layer surrounded by the channel layer, and a liner layer insulating the channel layer and the channel back gate layer from each other, wherein the channel layer is included in a first current path and the channel back gate layer is included in a second current path.

According to an embodiment, a memory device may include a stack structure including conductive layers and interlayer insulating layers, a channel layer penetrating the stack structure, a channel back gate layer surrounded by the channel layer, and a liner layer insulating the channel layer and the channel back gate layer from each other, wherein the channel layer and the channel back gate layer have different electrical paths from each other.

According to an embodiment, a method of manufacturing a memory device may include forming a channel layer penetrating a stack structure, forming a source layer contacting the channel layer over the stack structure, forming an opening penetrating the source layer and exposing an inner surface of the channel layer, forming a liner layer along an inner surface of the source layer exposed through the opening and the inner surface of the channel layer, and forming a channel back gate layer surrounded by the liner layer in the opening.

According to an embodiment, a memory device may include a stack structure including conductive layers and interlayer insulating layers, and cell plugs penetrating the stack structure, wherein each of the cell plugs include a channel layer, a channel back gate layer surrounded by the channel layer, and a liner layer insulating the channel layer and the channel back gate layer from each other, and wherein the channel layer and the channel back gate layer have different electrical paths from each other.

### BRIEF DESCRIPTION OF THE DRAWINGS

FIG. 1 is a diagram illustrating a memory device according to an embodiment of the present disclosure;

FIG. 2 is a diagram illustrating a cell plug according to an embodiment of the present disclosure;

FIGS. 3A, 3B, 3C, 3D, 3E, 3F, 3G, and 3H are diagrams illustrating a method of manufacturing a cell plug according to an embodiment of the present disclosure;

FIGS. 4A to 4B are diagrams illustrating a structure and operation of cell plugs according to an embodiment of the present disclosure;

FIG. 5 is a diagram illustrating a memory card system to which a memory device according to an embodiment of the present disclosure is applied; and

FIG. 6 is a diagram illustrating a solid state drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to implement the technical spirit of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly. Terms such as “first,” “second,” etc., are used to distinguish between various elements and do not imply size, order, priority, quantity, or importance of the elements. For example, a first element may be named as a second element in one example, and the second element may be named as a first element in another example. The cross-hatching throughout the figures illustrates corresponding or similar areas between the figures rather than indicating the materials associated with the areas. Various embodiments are directed to a method of manufacturing a memory device capable of enhancing the performance of program operations performed on memory cells.

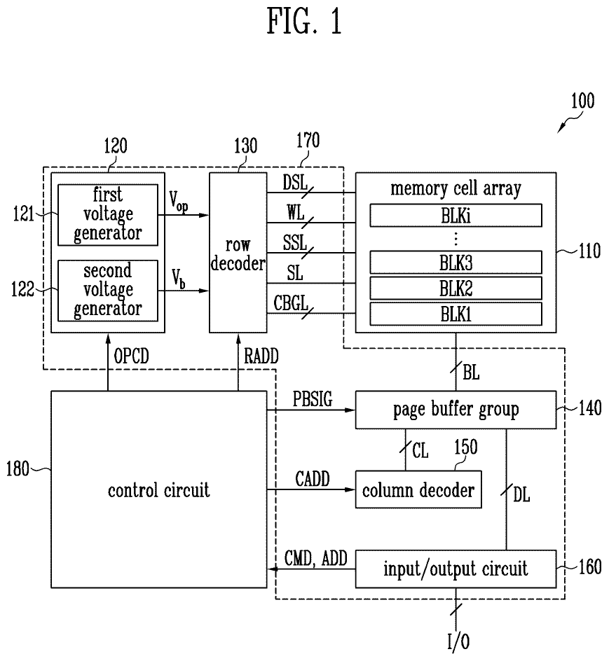

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

Each of the first to ith memory blocks BLK1 to BLKi may have a three-dimensional structure. Each of memory blocks having a three-dimensional structure may include memory cells stacked in a vertical direction (i.e., Z direction) on a substrate.

Each of the memory cells may store one-bit or two-or-more-bit data according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method. In addition, five-or-more-bit data may be stored in one memory cell.

The peripheral circuit 170 may be configured to perform a program operation that stores data in the memory cell array 110, a read operation that outputs data stored in the memory cell array 110, and an erase operation that erases data stored in the memory cell array 110. For example, the peripheral circuit 170 may include a voltage generator 120, a row decoder 130, a page buffer group 140, a column decoder 150, and an input/output circuit 160.

The voltage generator 120 may include a first voltage generator 121 and a second voltage generator 122.

The first voltage generator 121 may generate various operating voltages Vop used for a program operation, a read operation, or an erase operation in response to an operation code OPCD. For example, the first voltage generator 121 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the first voltage generator 121 may be applied to the drain select lines DSL, the word lines WL, the source select lines SSL, and the source line SL of a selected memory block through the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL, and may be used to turn on the drain select transistors or the source select transistors. The turn-off voltages may be applied to the drain select lines DSL or the source select lines SSL, and may be used to turn off the drain select transistors or the source select transistors. For example, the turn-off voltages may be set to 0 V. The pre-charge voltages may be higher than 0 V, and may be applied to the bit lines BL during a read operation. The verify voltages may be used during a verify operation to determine whether threshold voltages of selected memory cells have been increased to a target level. The verify voltages may be set to various levels according to the target level, and may be applied to the selected word line.

The read voltages may be applied to the selected word line during a read operation of the selected memory cells. For example, the read voltages may be set to various levels according to a program method of the selected memory cells. The pass voltages may be applied to unselected word lines among the word lines WL during a program or read operation, and may be used to turn on memory cells coupled to the unselected word lines. The erase voltages may be used during an erase operation to erase memory cells included in the selected memory block, and may be applied to the source line SL.

The second voltage generator 122 may generate various back voltages Vb used for a program operation, a read operation, or an erase operation in response to the operation code OPCD. The back voltages Vb generated by the second voltage generator 122 may be applied to common back gate lines CBGL of a selected memory block through the row decoder 130.

The row decoder 130 may be configured to transfer the operating voltages Vop to the drain select lines DSL, the word lines WL, the source select lines SSL, and the source line SL that are coupled to a memory block selected according to a row address RADD. In addition, the row decoder 130 may be configured to transfer the back voltages Vb to the common back gate lines CBGL coupled to the selected memory block according to the row address RADD. For example, the row decoder 130 may be coupled to the first and second voltage generators 121 and 122 through global lines, and may be coupled to the first to ith memory blocks BLK1 to BLKi through the drain select lines DSL, the word lines WL, the source select lines SSL, and the source line SL.

The page buffer group 140 may include page buffers (not shown) respectively coupled to the first to ith memory blocks BLK1 to BLKi. The page buffers (not shown) may be coupled to the first to ith memory blocks BLK1 to BLKi through the bit lines BL, respectively. During a read operation, the page buffers (not shown) may sense a current or a voltage of the bit lines BL that varies according to the threshold voltages of the selected memory cells and may store sensed data in response to page buffer control signals PBSIG.

The column decoder 150 may be configured to transfer data between the page buffer group 140 and the input/output circuit 160 in response to a column address CADD. For example, the column decoder 150 may be coupled to the page buffer group 140 through column lines CL and may transfer enable signals through the column lines CL. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer the command CMD and the address ADD, which are received from an external controller through the input/output lines I/O, to the control circuit 180, and may transfer data, which is received from the external controller through the input/output lines I/O, to the page buffer group 140. Alternatively, the input/output circuit 160 may output data transferred from the page buffer group 140 to the external controller through the input/output lines I/O.

The control circuit 180 may output at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 may control the peripheral circuit 170 to perform the program operation of a memory block selected by the address ADD. When the command CMD input to the control circuit 180 corresponds to a read operation, the control circuit 180 may control the peripheral circuit 170 to perform the read operation of the memory block selected by the address ADD and to output read data. When the command CMD input to the control circuit 180 corresponds to an erase operation, the control circuit 180 may control the peripheral circuit 170 to perform the erase operation of the selected memory block.

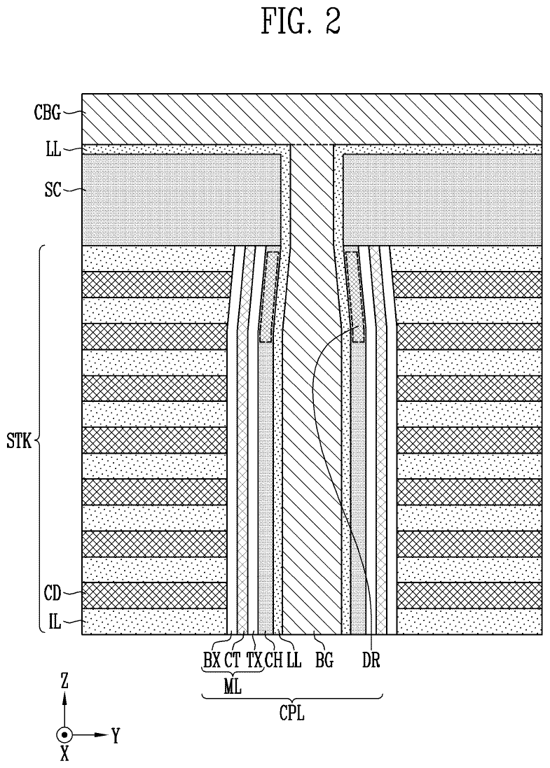

FIG. 2 is a diagram illustrating a cell plug CPL according to an embodiment of the present disclosure.

Referring to FIG. 2, the memory device 100 may include a stack structure STK. The stack structure STK may include conductive layers CD and interlayer insulating layers IL. The conductive layers CD and the interlayer insulating layers IL may be alternately stacked in a Z direction. The conductive layers CD may include at least one of tungsten (W), cobalt (Co), nickel (Ni), molybdenum (Mo), silicon (Si), and polysilicon (poly-Si). The interlayer insulating layers IL may include an oxide layer (e.g., a silicon oxide layer). Each of the conductive layers CD may correspond to the drain select line DSL, the word line WL, or the source select line SSL in FIG. 1.

The memory device 100 may include the cell plug CPL. The cell plug CPL may penetrate the stack structure STK. For example, the cell plug CPL may penetrate the conductive layers CD and the interlayer insulating layers IL. The cell plug CPL may extend in the Z direction. The memory cells or the select transistors described with reference to FIG. 1 may be respectively formed at intersections of the cell plug CPL and the conductive layers CD.

The cell plug CPL may include a memory layer ML. The memory layer ML may include a blocking layer BX, a charge trap layer CT, and a tunneling layer TX. The memory layer ML may extend in the Z direction in the stack structure STK. The memory layer ML may penetrate the stack structure STK. For example, the blocking layer BX may contact an inner side surface of the stack structure STK. The charge trap layer CT may contact an inner side surface of the blocking layer BX. The tunnel insulating layer TX may contact an inner side surface of the charge trap layer CT. The memory layer ML may extend along an outer side surface of the channel layer CH. For example, the tunnel insulating layer TX may contact the outer side surface of the channel layer CH. The blocking layer BX and the tunnel insulating layer TX may include an oxide layer (e.g., a silicon oxide layer) or an oxynitride layer (e.g., a silicon oxynitride layer), or a combination thereof. The charge trap layer CT may include a nitride layer or a variable resistance material.

The cell plug CPL may include the channel layer CH. The channel layer CH may extend in the Z direction in the stack structure STK. The channel layer CH may penetrate the stack structure STK. The channel layer CH may have a cylindrical shape. The channel layer CH may contact an inner side surface of the tunnel insulating layer TX. The channel layer CH may include an undoped silicon layer or a doped silicon layer.

The channel layer CH may include a doping region DR. The doping region DR may include an impurity. The impurity doped into the doping region DR may include an n-type impurity (e.g., an element of group 15 such as phosphorus (P) or arsenic (As)) or a p-type impurity (e.g., an element of group 13 such as boron (B)). The impurity injected into the doping region DR may be distributed around a level corresponding to the source select line SSL of FIG. 1 among the conductive layers CD. For example, among the conductive layers CD shown in FIG. 2, an uppermost conductive layer CD and a second conductive layer CD from the top may correspond to the source select line SSL. For example, as shown in FIG. 2, the doping region DR horizontally overlaps (i.e., in the Y direction) with an uppermost conductive layer and a second conductive layer from the top of the stack structure. According to the method of the impurity injection process (e.g., a tilt angle or an injection dose), the distribution pattern and the maximum concentration of each impurity may vary.

The cell plug CPL may include a channel back gate layer BG. At least a portion of the channel back gate layer BG may be surrounded by the channel layer CH. The channel back gate layer BG may fill at least portion of the area surrounded by the channel layer CH. The channel back gate layer BG may extend in a vertical direction (e.g., Z direction). The channel back gate layer BG may penetrate at least a portion of the stack structure STK. For example, the channel back gate layer BG may penetrate the conductive layers CD and the interlayer insulating layers IL. The channel back gate layer BG may include polysilicon or metal (e.g., tungsten (W), molybdenum (Mo), tantalum (Ta)).

The cell plug CPL may include a liner layer LL. The liner layer LL may insulate the channel layer CH and the channel back gate layer BG from each other. The liner layer LL may extend between the channel layer CH and the channel back gate layer BG. The liner layer LL may contact an inner side surface of the channel layer CH and an outer side surface of the channel back gate layer BG. The channel back gate layer BG may be spaced apart from the channel layer CH by the liner layer LL. The liner layer LL may include an insulating layer. For example, the liner layer LL may be an oxide layer, an oxynitride layer, or a metal-doped oxide layer.

The channel back gate layer BG may have a cylindrical shape extending in the Z direction. The channel layer CH may have a cylindrical shape that surrounds the channel back gate layer BG and the liner layer LL and extends in the Z direction. The memory layer ML may surround the channel back gate layer BG, the liner layer LL, and the channel layer CH. In an embodiment, the plane diameters of the channel back gate layer BG and the channel layer CH may vary depending on the locations in the Z direction. For example, as shown in FIG. 2, the width of the cell plug CPL in a horizontal direction (i.e., Y direction) may vary. Therefore, the shape of the channel back gate layer BG may be a cylindrical shape in some areas and a truncated cone shape in other areas.

The channel back gate layer BG may be insulated from the conductive layers CD of the stack structure STK. The channel back gate layer BG may be separated from the conductive layers CD by the memory layer ML, the channel layer CH, and the liner layer LL. The channel back gate layer BG may form a separate current path from the conductive layers CD.

A source layer SC may be disposed over the stack structure STK. The source layer SC may correspond to the source line SL of FIG. 1. The source layer SC may be disposed in the Z direction with respect to the stack structure STK. The source layer SC may cover the stack structure STK. The source layer SC may contact an uppermost interlayer insulating layer IL among the interlayer insulating layers IL. The source layer SC may contact an upper surface of the memory layer ML. The source layer SC may contact the channel layer CH. The source layer SC may be electrically coupled to the channel layer CH. The source layer SC may include at least one of n-type impurities (e.g., an element of group 15) and p-type impurities (e.g., an element of group 13).

A common back gate layer CBG may be disposed over the source layer SC. The common back gate layer CBG may correspond to the common back gate line CBGL of FIG. 1. The common back gate layer CBG may be disposed in the Z direction with respect to the source layer SC. The common back gate layer CBG may cover the stack structure STK, cell plug CPL, and source layer SC. The common back gate layer CBG may extend in the horizontal direction (e.g., in an Y direction). The common back gate layer CBG may include the same material as the channel back gate layer BG. The common back gate layer CBG may include polysilicon or metal (e.g., tungsten (W), molybdenum (Mo), tantalum (Ta)).

The channel back gate layer BG may penetrate the source layer SC. The channel back gate layer BG may contact the common back gate layer CBG. An upper surface of the channel back gate layer BG may contact a lower surface of the common back gate layer CBG. The channel back gate layer BG may be electrically coupled to the common back gate layer CBG. The channel back gate layer BG may extend in the Z direction than the channel layer CH. The channel back gate layer BG may protrude toward the common back gate layer CBG further than the channel layer CH. The upper surface of the channel back gate layer BG may protrude toward the common back gate layer CBG further than an upper surface of the channel layer CH. The upper surface of the channel back gate layer BG may protrude toward the common back gate layer CBG further than an upper surface of the stack structure STK.

The liner layer LL may extend between the channel back gate layer BG and the source layer SC. In addition, the liner layer LL may extend between the common back gate layer CBG and the source layer SC. The liner layer LL may insulate the source layer SC from the channel back gate layer BG and the common back gate layer CBG. That is, the channel back gate layer BG and the common back gate layer CBG may be insulated from the channel layer CH and the source layer SC by the liner layer LL.

Therefore, the channel layer CH and the channel back gate layer BG may have different current paths. For example, the channel layer CH and the source layer SC may form a first current path, and the channel back gate layer BG and the common back gate layer CBG may form a second current path. The first current path and the second current path may be insulated from each other. In addition, at least one of the conductive layers CD may form a third current path. The third current path may be insulated from the first current path and the second current path. Accordingly, in an embodiment, different voltages may be applied to the first to third current paths when the memory device is operating.

In FIG. 2, the channel back gate layer BG and the common back gate layer CBG are illustrated as having different configurations from each other for convenience of description, but the scope of the present disclosure is not limited thereto. For example, the channel back gate layer BG and the common back gate layer CBG may be integrally formed. The interface between the channel back gate layer BG and the common back gate layer CBG might not be observed. The channel back gate layer BG and the common back gate layer CBG may include the same material. The common back gate layer CBG may have a plate shape extending in at least one direction, and the channel back gate layer BG may have a column shape protruding from one surface of the common back gate layer BCG.

In an embodiment, the cell plug CPL may include the channel back gate layer BG that forms a different current path from the channel layer CH. Because the channel back gate layer BG is insulated from the channel layer CH and the conductive layers CD, a voltage (e.g., the back voltage Vb of FIG. 1) different from the voltage (e.g., the operating voltages Vop of FIG. 1) applied to the channel layer CH or the conductive layers CD may be applied to the channel back gate layer BG. In an embodiment, when memory cells are programmed by applying the operating voltages Vop to the channel CH and the conductive layers CD and applying the back voltage Vb to the channel back gate layer BG, the performance of the program operation may be improved, as compared with the case where the memory cells are programed by applying the operating voltages Vop to the channel CH layer and conductive layers CD. For example, according an embodiment, the program speed of a memory cell may increase and the interference by other memory cells may decrease.

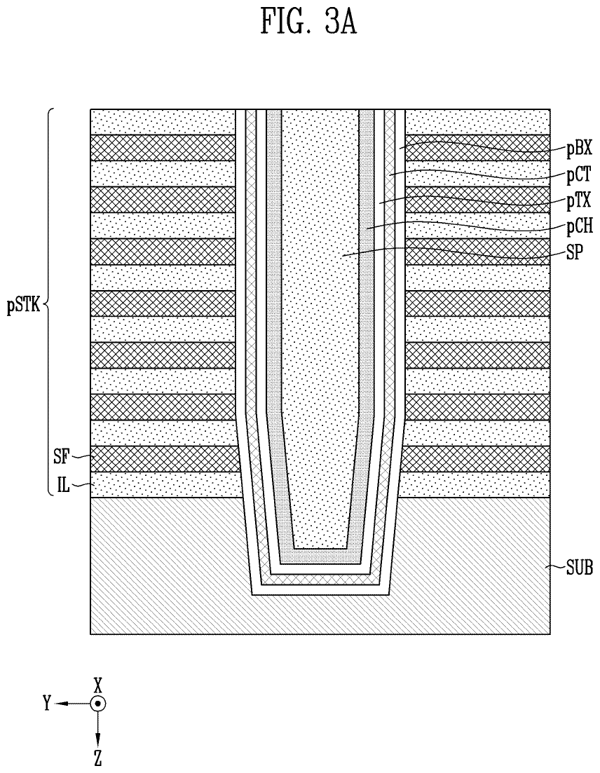

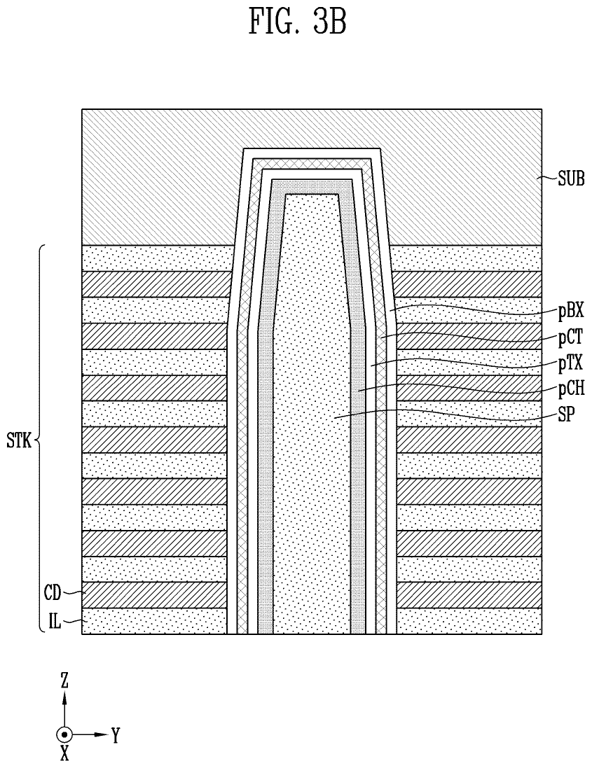

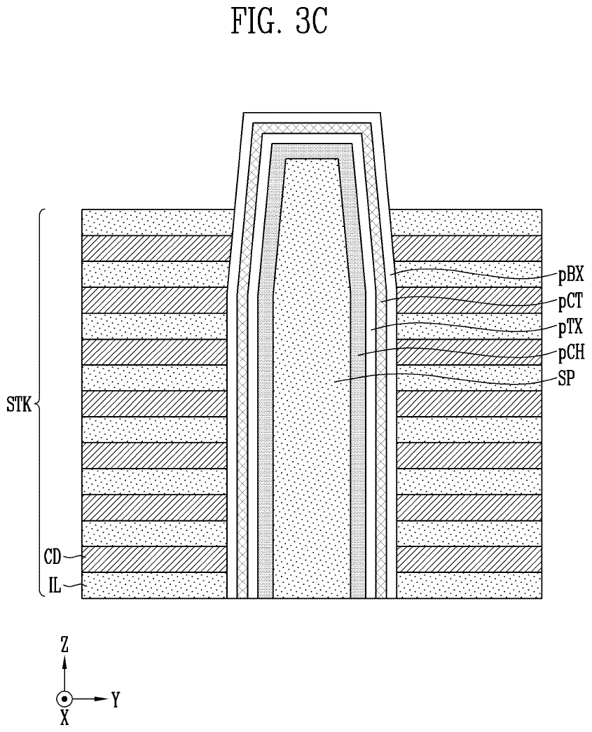

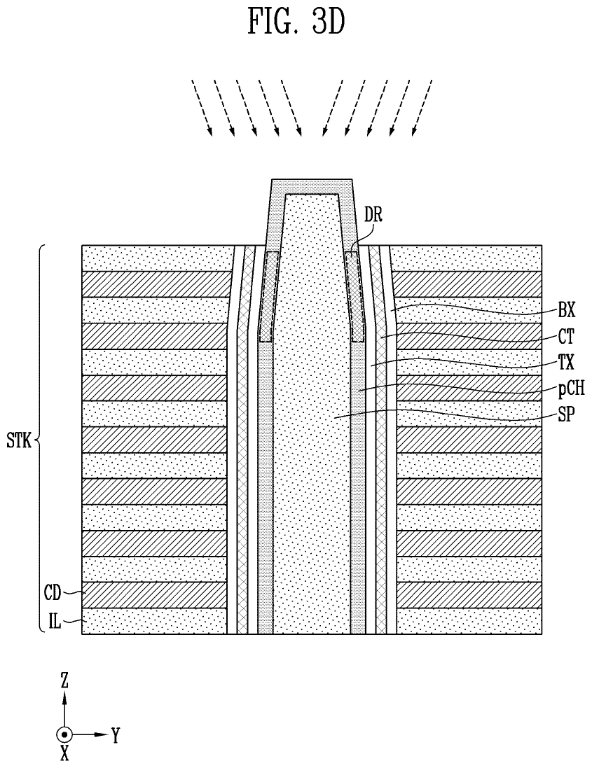

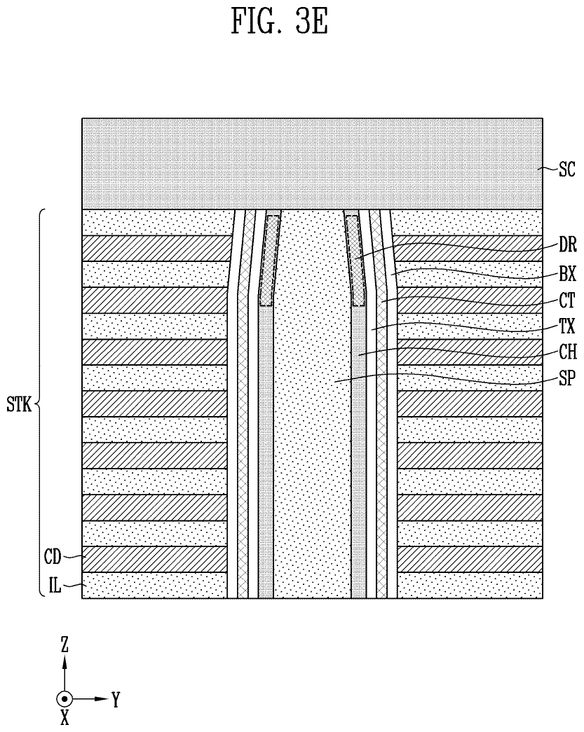

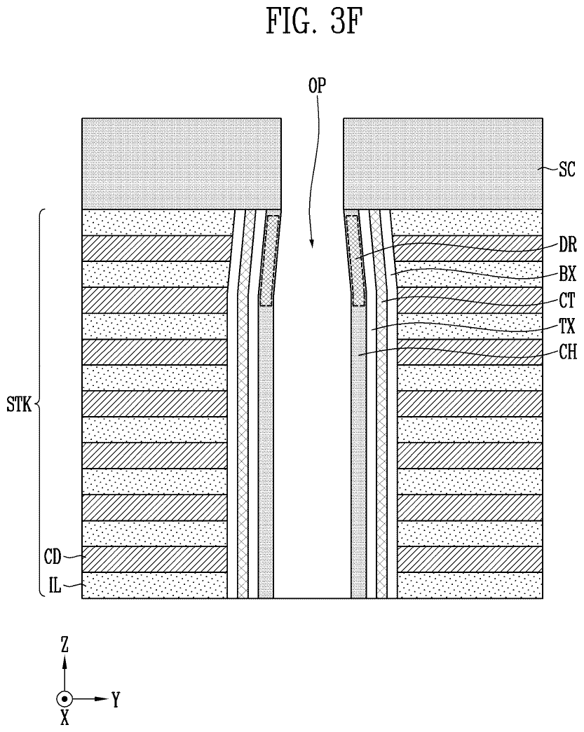

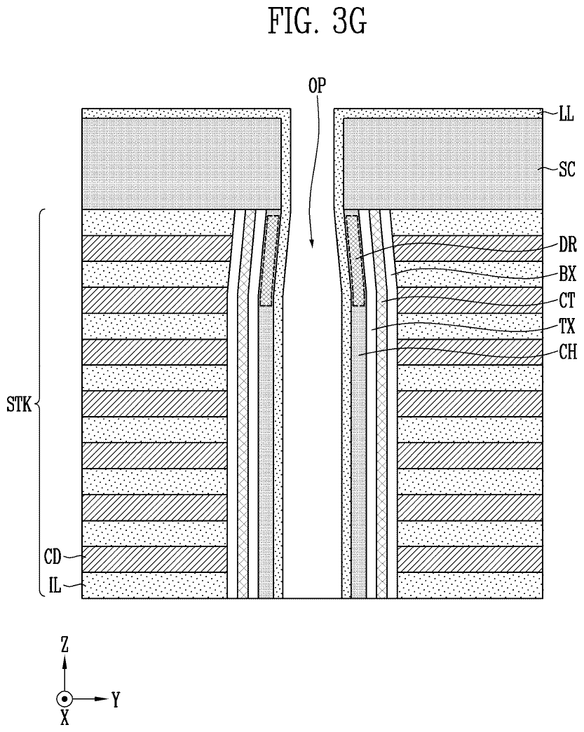

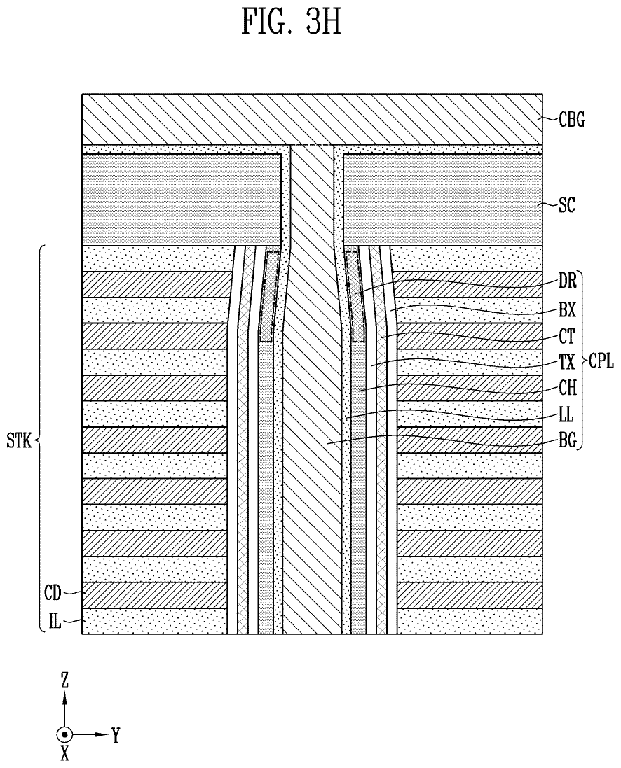

FIGS. 3A to 3H are diagrams illustrating a method of manufacturing the cell plug CPL according to an embodiment of the present disclosure.

Referring to FIG. 3A, a preliminary stack structure pSTK may be formed over a substrate SUB. The preliminary stack structure pSTK may include first material layers IL and second material layers SF alternately stacked in the Z direction. The first material layers IL may include an insulating material. For example, the first material layers IL may include an oxide layer (e.g., a silicon oxide layer). The second material layers SF may include a material which may be selectively removed in a subsequent process. Accordingly, the second material layers SF may include a material having different etch selectivity from the first material layers IL. For example, the sacrificial layers SF may include a nitride material.

Subsequently, a cell opening penetrating the preliminary stack structure pSTK may be formed. The cell opening may penetrate the first and second material layers IL and SF of the preliminary stack structure pSTK. The cell opening may expose inner side surfaces of the first and second material layers IL and SF. The cell opening may extend in the Z direction. The cell opening may extend into the substrate SUB. The cell opening may expose an inner surface of the substrate SUB. The cell opening may have a hole shape.

Subsequently, a preliminary blocking layer pBX, a preliminary charge trap layer pCT, a preliminary tunnel insulating layer pTX, and a preliminary channel layer pCH may be sequentially formed in the cell opening. The preliminary blocking layer pBX may be formed along the inner side surfaces of the first and second material layers IL and SF. The preliminary blocking layer pBX may be formed along the inner surface of the substrate SUB. The preliminary tunnel insulating layer pTX may be formed along an inner surface of the preliminary charge trap layer pCT. The preliminary channel layer pCH may be formed along an inner surface of the preliminary tunnel insulating layer pTX. The preliminary channel layer pCH may be conformally formed on the inner surface of the preliminary tunnel insulating layer pTX.

Each of the preliminary blocking layer pBX, the preliminary charge trap layer pCT, the preliminary tunnel insulating layer pTX, and the preliminary channel layer pCH may penetrate the preliminary stack pSTK. Each of the preliminary blocking layer pBX, the preliminary charge trap layer pCT, the preliminary tunnel insulating layer pTX, and the preliminary channel layer pCH may extend into the substrate SUB. The preliminary blocking layer pBX and the preliminary tunnel insulating layer pTX may include an oxide layer (e.g., a silicon oxide layer), an oxynitride layer (e.g., a silicon oxynitride layer), or a combination thereof. The preliminary charge trap layer pCT may include a nitride layer or a variable resistance material. The preliminary channel layer pCH may include an undoped silicon layer or a doped silicon layer.

Subsequently, a sacrificial pillar SP surrounded by the preliminary channel layer pCH may be formed. The sacrificial pillar SP may fill in the preliminary channel layer pCH. The sacrificial pillar SP may extend in the Z direction in the preliminary stack structure pSTK. The sacrificial pillar SP may extend into the substrate SUB. The sacrificial pillar SP may include a material having a different etching selectivity from the preliminary channel layer pCH. For example, the sacrificial pillar SP may include a nitride layer or an oxide layer.

Referring to FIG. 3B, the second material layers SF may be replaced with third material layers CD. For example, an etching process may be performed to remove the second material layers SF. Because the second material layers SF are formed between the first material layers IL, the etching process may be performed by an isotropic dry etching process or a wet etching process. The second material layers SF may be removed to form empty spaces between the first material layers IL. The third material layers CD may be formed in the empty spaces. The third material layers CD may include a conductive layer. The third material layers CD may include at least one of tungsten (W), cobalt (Co), nickel (Ni), molybdenum (Mo), silicon (Si), and polysilicon (poly-Si), and may include various other conductive layers. The first material layers IL and the third material layers CD may form the stack structure STK.

Subsequently, the stack structure STK may be flipped over. When the stack structure STK is flipped over, the substrate SUB may be located over the stack structure STK. The flipped stack structure STK may be bonded to a separate peripheral circuit structure (not shown). Although the peripheral circuit structure is not shown in the present disclosure, the peripheral circuit structure may be disposed under the stack structure STK.

Referring to FIG. 3C, the substrate SUB may be removed. An isotropic wet etching process may be performed to etch the substrate SUB. A portion of the preliminary blocking layer pBX as the substrate SUB is removed.

Referring to FIG. 3D, the portion of the preliminary blocking layer pBX may be removed to form the blocking layer BX. The portion of the preliminary blocking layer pBX, which is exposed to the outside as the substrate SUB is removed, may be etched. Subsequently, a portion of the preliminary charge trap layer pCT may be removed to form the charge trap layer CT. The portion of the preliminary charge trap layer pCT, which is exposed to the outside as the portion of the preliminary blocking layer pBX is removed, may be etched. Subsequently, a portion of the preliminary tunnel insulating layer pTX may be removed to form the tunnel insulating layer TX. The portion of the preliminary tunnel insulating layer pTX, which is exposed to the outside as the portion of the preliminary charge trap layer pCT is removed, may be etched.

In an embodiment, upper surfaces of the blocking layer BX, the charge trap layer CT, and the tunnel insulating layer TX may be located at the same level as the upper surface of the stack structure STK. In another embodiment, the preliminary blocking layer pBX, the preliminary charge trap layer pCT, and the preliminary tunnel insulating layer pTX may be over-etched, so that the upper surfaces of the blocking layer BX, the charge trap layer CT, and the tunnel insulating layer TX may be located lower than the upper surface of the stack structure STK.

Subsequently, the doping region DR may be formed in the preliminary channel layer pCH. As indicated by the arrowed dotted lines, an impurity may be injected into one region of the preliminary channel layer pCH to form the doping region DR. For example, an n-type impurity (e.g., an element of group 15 such as phosphorus (P) or arsenic (As)) or a p-type impurity (e.g., an element of group 13 such as boron (B)) may be doped into the doping region DR. In an embodiment, the impurity may be injected into the doping region DR through a tilting ion implantation process. The tilting ion implantation process may be an ion implantation process in which the angle formed between the direction in which the impurity is implanted and the upper surface of the stack structure STK is less than an angle of 90. For example, the doping region DR may be formed through an impurity implantation process with a tilt at an angle of 35 degrees. The doping region DR may be formed by injecting the impurity at a depth corresponding to the first and second third material layers CD (e.g., conductive layers CD corresponding to the source select line SSL of FIG. 1) from the top.

Referring to FIG. 3E, a portion of the preliminary channel layer pCH may be removed to form the channel layer CH. The portion of the preliminary channel layer pCH that protrudes onto the stack structure STK may be removed. For example, the portion of the preliminary channel layer pCH may be removed through a process of flattening the upper surface of the stack structure STK. When the portion of the preliminary channel layer pCH is removed, a portion of the sacrificial pillar SP may be removed. For example, the portion of the preliminary channel layer pCH and the portion of the sacrificial pillar SP may be removed through the process of flattening the upper surface of the stack structure STK.

Subsequently, the source layer SC may be formed over the stack structure STK. The source layer SC may cover the stack structure STK. The source layer SC may contact the upper surface of the stack structure STK. The source layer SC may contact the upper surfaces of the blocking layer BX, the charge trap layer CT, and the tunnel insulating layer TX. The source layer SC may contact the channel layer CH. The source layer SC may contact an upper surface of the sacrificial pillar SP.

Referring to FIG. 3F, an opening OP penetrating the source layer SC, the first material layers IL, and the third material layers CD may be formed. The opening OP may expose an inner side surface of the source layer SC. The opening OP may expose the inner side surface of the channel layer CH. For example, a portion of the source layer SC may be etched to expose the sacrificial pillar SP, and the exposed sacrificial pillar SP may be removed to form the opening OP. The opening OP may extend in the Z direction. The opening OP may penetrate at least a portion of the stack structure STK.

Referring to FIG. 3G, the liner layer LL may be formed along the opening OP. The liner layer LL may be formed along the inner side surface of the source layer SC exposed through the opening OP. In addition, the liner layer LL may be formed along the inner side surface of the channel layer CH exposed through the opening OP. In addition, the liner layer LL may be formed along an upper surface of the source layer SC. The liner layer LL may be conformally formed along surfaces of the source layer SC and the channel layer CH. For example, the liner layer LL may be formed by depositing an insulating material over the entire structure including the stack structure STK and the source layer SC.

Referring to FIG. 3H, the channel back gate layer BG may be formed in the opening OP. The channel back gate layer BG may fill in the opening OP where the liner layer LL is formed. A portion of the channel back gate layer BG may be surrounded by the channel layer CH with the liner layer LL interposed therebetween. The channel back gate layer BG may be insulated from the channel layer CH by the liner layer LL. Another portion of the channel back gate layer BG may be surrounded by the source layer SC with the liner layer LL interposed therebetween. The channel back gate layer BG may be insulated from the source layer SC by the liner layer LL.

In addition, the common back gate layer CBG may be formed over the source layer SC. The common back gate layer CBG may cover the source layer SC and the stack structure STK. The common back gate layer CBG may contact an upper surface of the liner layer LL. The common back gate layer CBG may be spaced apart from the source layer SC by the liner layer LL. The common back gate layer CBG may be insulated from the source layer SC by the liner layer LL.

The channel back gate layer BG and the common back gate layer CBG may be formed simultaneously. The channel back gate layer BG and the common back gate layer CBG may be integrally formed. For example, the channel back gate layer BG and the common back gate layer CBG may be formed by depositing polysilicon or a metal material on the entire structure including the opening OP. That is, a portion of the deposited polysilicon or the metal material located in the opening OP may be referred to as the channel back gate layer BG, and a portion located outside the opening OP is referred to as the common back gate layer CBG. Accordingly, the common back gate layer CBG may extend with respect to the channel back gate layer BG. In addition, the common back gate layer CBG may be electrically coupled to the channel back gate layer BG. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

A chemical vapor deposition (CVD) process or an atomic layer deposition (ALD) process may be used as a method of depositing the channel back gate layer BG and the common back gate layer CBG. In an embodiment, in order to reduce voids or seams generated in the channel back gate layer BG, conditions such as the concentration of precursors in the CVD process or ALD process may be variously adjusted.

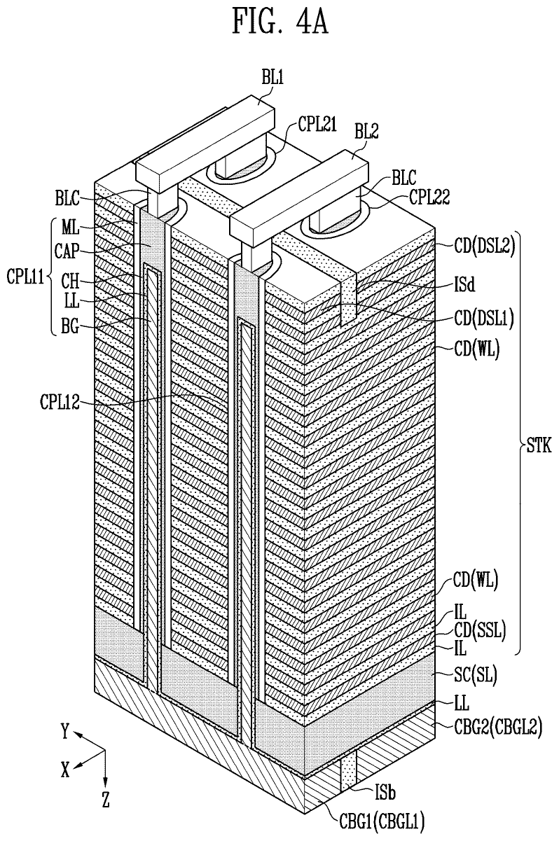

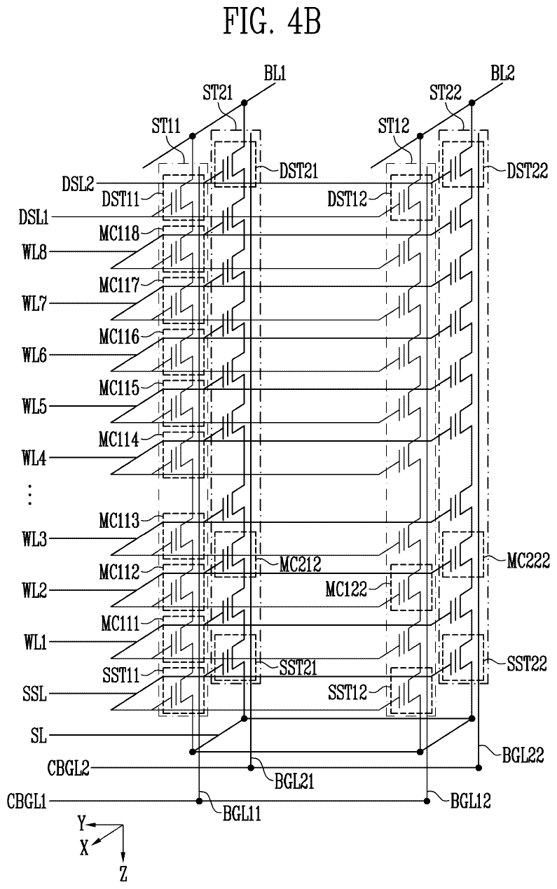

FIGS. 4A to 4B are diagrams illustrating a structure and operation of the cell plugs CPL according to an embodiment of the present disclosure. FIGS. 4A and 4B are diagrams for explaining how the cell plug CPL illustrated in FIGS. 2 and 3A to 3H is connected to other cell plugs CPL and how the cell plugs CPL operate. In connection with FIGS. 4A and 4B, a detailed description of the configurations that have already been described with reference to FIGS. 1, 2, and 3A to 3H will be omitted or simplified. In addition, FIGS. 4A and 4B illustrate the flipped memory device 100 shown in FIG. 2, so the Z direction is illustrated as to indicate the bottom of the figure.

Referring to FIG. 4A, the memory device 100 may include the stack structure STK in which the conductive layers CD and the interlayer insulating layers IL are alternately stacked. A portion of the conductive layers CD may correspond to the drain selection lines DSL of FIG. 1, another portion of the conductive layers CD may correspond to the word lines WL of FIG. 1, and another portion of the conductive layers CD may correspond to the source selection lines SSL of FIG. 1. For example, the conductive layer CD which is located in the Z direction among the conductive layers CD may serve as the source selection line SSL. The conductive layers CD located in an opposite direction to the Z direction among the conductive layers CD may serve as first and second drain select lines DSL1 and DSL2. In addition, among the conductive layers CD, the conductive layers CD located between the source select line SSL and the first and second drain select lines DSL1 and DSL2 may serve as the word lines WL. In FIG. 4A, the number of layers of the drain select lines DSL and the source select lines SSL does not limit the scope of the present disclosure. For example, two or more conductive layers CD may serve as the drain select lines DSL.

The first and second drain select lines DSL1 and DSL2 may be separated by a drain isolation structure ISd. The first and second drain select lines DSL1 and DSL2 may be spaced apart from each other in a X direction. Each of the first and second drain select lines DSL1 and DSL2 may extend in the Y direction. The drain isolation structure ISd may penetrate at least one layer of the conductive layer CD. The drain isolation structure ISd may extend in the Y direction in the stack structure STK. The drain isolation structure ISd may insulate the first drain select line DSL1 and the second drain select line DSR2 from each other. The conductive layers CD located at the same level may be separated into the first drain select line DSL1 and second select line DSL2 by the drain isolation structure ISd. The drain isolation structure ISd may include an insulating material. In FIG. 4A, the drain isolation structure ISd is illustrated as to penetrate two conductive layers CD, but the length of the drain isolation structure ISD in the Z direction may vary depending on the number of layers of the drain select lines DSL.

Cell plugs CPL11, CPL12, CPL21, and CPL22 may be located in the stack structure STK. Each of the cell plugs CPL11, CPL12, CPL21, and CPL22 may extend in the Z direction. Each of the cell plugs CPL11, CPL12, CPL21, and CPL22 may penetrate the stack structure STK. The cell plugs CPL11, CPL12, CPL21, and CPL22 may be spaced apart from each other in the X direction and the Y direction. The cell plugs CPL11, CPL12, CPL21, CPL22 may be arranged in the X direction or in the Y direction. For example, the cell plug CPL11 may be adjacent to the cell plug CPL21 in the X direction, and the cell plug CPL12 may be adjacent to the cell plug CPL22 in the X direction. Alternately, the cell plug CPL11 may be adjacent to the cell plug CPL12 in the Y direction, and the cell plug CPL21 may be adjacent to the cell plug CPL22 in the Y direction.

Each of the cell plugs CPL11, CPL12, CPL21, and CPL22 may include the memory layer ML, the channel layer CH, the liner layer LL, and the channel back gate layer BG. Each of the memory layer ML, the channel layer CH, the liner layer LL, and the channel back gate layer BG may extend in the Z direction. The memory layer ML and the channel layer CH may penetrate the stack structure STK. The channel back gate layer BG may penetrate a portion of the conductive layers CD. For example, the upper surface of the channel back gate layer BG may be located lower than the upper surface of the stack structure STK. At least the portion of the channel back gate layer BG may be surrounded by the channel layer CH. The liner layer LL may be located between the channel back gate layer BG and the channel layer CH. The channel layer CH and the channel back gate layer BG may have different current paths due to the liner layer LL.

Each of the cell plugs CPL11, CPL12, CPL21, and CPL22 may include a capping layer CAP coupled to the channel layer CH. The capping layer CAP may contact a portion of the inner side surface of the channel layer CH. The capping layer CAP may be located over the channel back gate layer BG. The capping layer CAP may be disposed between the channel back gate layer BG and first bit line BL1 or second bit line BL2. The liner layer LL may be located between the capping layer CAP and the channel back gate layer BG. The liner layer LL may extend between the capping layer CAP and the channel back gate layer BG. The liner layer LL may insulate the channel back gate layer BG from the capping layer CAP and the channel layer CH.

The first and second bit lines BL1 and BL2 may be disposed over the stack structure STK. The first and second bit lines BL1 and BL2 may be located in directions opposite to the Z direction of the stack structure STK. The first and second bit lines BL1 and BL2 may correspond to the bit lines BL of FIG. 1. The first bit line BL1 may be spaced apart from the second bit line BL2 in the Y direction. Each of the first bit line BL1 and the second bit line BL2 may extend in the X direction. The first and second bit lines BL1 and BL2 may be coupled to the cell plugs CPL11, CPL12, CPL21, and CPL22 through bit line contacts BLC. At least one of the channel layer CH or the capping layer CAP of each of the cell plugs CPL11, CPL12, CPL21, and CPL22 may contact the bit line contact BLC. The channel layer CH of each of the cell plugs CPL11, CPL12, CPL21, and CPL22 may be electrically coupled to the first bit line BL1 or the second bit line BL2 via the bit line contact BLC.

The first bit line BL1 may be commonly coupled to the cell plugs CPL11 and CPL21 adjacent in the X direction. The first bit line BL1 may be electrically coupled to the channel layers CH included in the cell plugs CPL11 and CPL21 arranged in the X direction. The second bit line BL2 may be commonly coupled to the cell plugs CPL12 and CPL22 adjacent in the X direction. The second bit line BL2 may be electrically coupled to the channel layers CH included in the cell plugs CPL12 and CPL22 adjacent in the X direction.

The source layer SC may be disposed under the stack structure STK. The source layer SC may be located in the Z direction with respect to the stack structure STK. The source layer SC may correspond to the source line SL of FIG. 1. The source line SL may contact the channel layer CH of each of the cell plugs CPL11, CPL12, CPL21, and CPL22. The source line SL may be electrically coupled to the channel layer CH of each of the cell plugs CPL11, CPL12, CPL21, and CPL22. One end of the channel layer CH of each of the cell plugs CPL11, CPL12, CPL21, and CPL22 may contact the bit line contact BLC, and the other end may contact the source layer SC.

The source layer SC may be commonly coupled to the cell plugs CPL11, CPL12, CPL21, and CPL22. The source layer SC may contact the channel layers CH included in the cell plugs CPL11, CPL12, CPL21, and CPL22. For example, the source layer SC may be commonly coupled to the channel layers CH included in the cell plugs adjacent in the X direction and the cell plugs in the Y direction (e.g., CPL11 and CPL21).

First common back gate layer CBG1 and second common back gate layer CBG2 may be disposed under the source layer SC. The first and second common back gate layers CBG1 and CBG2 may be located in the Z direction of the stack structure STK with the source layer SC interposed therebetween. The first and second common back gate layers CBG1 and CBG2 may be located in a direction opposite to the bit lines BL1 and BL2 with respect to the stack structure STK. Each of the first and second common back gate layers CBG1 and CBG2 may extend in the Y direction. The first and second common back gate layers CBG1 and CBG2 may be spaced apart from each other in the X direction. The first and second common back gate layers CBG1 and CBG2 may serve as first and second common back gate lines CBGL1 and CBGL2, respectively.

The first and second common back gate layers CBG1 and CBG2 may be separated by the back gate isolation structure ISb. The back gate isolation structure ISb may extend in the Y direction. The back gate isolation structure ISb may penetrate the common back gate layer CBG. The back gate isolation structure ISb may insulate the first common back gate layer CBG1 and the second common back gate layer BCG2 from each other. The back gate isolation structure (ISb) may include an insulating material.

The first common back gate layer CBG1 may be commonly coupled to the cell plugs CPL11 and CPL12 adjacent in the Y direction. The first common back gate layer CBG1 may be electrically coupled to the channel back gate layers BG included in the cell plugs CPL11 and CPL12 arranged in the Y direction. The second common back gate layer CBG2 may be commonly coupled to the cell plugs CPL21 and CPL22 adjacent in the Y direction. The second common back gate layer CBG2 may be electrically coupled to the channel back gate layers BG included in the cell plugs CPL21 and CPL22 arranged in the Y direction.

The liner layer LL may extend between the source layer SC and the first common back gate layer CBG1, between the source layer SC and the second common back gate layer BCG2, and between the source layer SC and the channel back gate layers BG. The channel back gate layers BG and the first and second common back gate layers CBG1 and CBG2 may be insulated from the channel layers CH, the source layer SC, and the first and the second bit lines BL1 and BL2 by the liner layer LL. Accordingly, the channel layers CH, the bit lines BL1 and BL2, and the source layer SC may form a different current path from the channel back gate layers BG and the common back gate layers CBG1 and CBG2.

For example, to describe the current path based on the cell plug CPL11, the channel CH of the cell plug CPL11 may form the first current path together with the first bit line BL1 and the source layer SC. Because the first current path and the second current path are insulated from each other, different voltages may be applied to the channel layer CH and the channel back gate layer BG of the cell plug CPL11. In addition, at least one of the conductive layers CD may form the third current path. The third current path may be insulated from the first and second current paths. Therefore, voltages different from those of the channel layer CH and the channel back gate layer BG may be applied to the conductive layers CD.

FIG. 4B is a circuit diagram of the components illustrated in FIG. 4A. Cell strings ST11, ST12, ST21, and ST22 may respectively correspond to the cell plugs CPL11, CPL12, CPL21, and CPL22 in FIG. 4A. Each of the cell strings ST11, ST12, ST21, and ST22 may be arranged in the X direction and the Y direction, and may extend in the Z direction. The cell strings ST11, ST12, ST21, and ST22 may be spaced apart from each other in the X direction and the Y direction. Each of the cell strings ST11, ST12, ST21, and ST22 may include memory cells electrically coupled to each other in the Z direction. For example, the cell string ST11 may include memory cells MC111 to MC118 electrically coupled to each other in the Z direction. Each of the cell strings ST11, ST12, ST21, and ST22 may include select transistors coupled to the memory cells in the Z direction. For example, the cell string ST11 may include a drain select transistor DST11 and a source select transistor SST11 connected to opposite ends of the memory cells MC111 to MC118. However, what is illustrated in FIG. 4B is an example, and the number of memory cells, the number of selected transistors, the presence or absence of dummy cells, or the like do not limit the scope of the present disclosure. For example, the dummy cell may be formed between the drain select transistor DST11 and the memory cell MC118.

Each of the first and second bit lines BL1 and BL2 may extend in the X direction. The first and second bit lines BL1 and BL2 may be coupled to one end of the cell strings ST11, ST12, ST21, and ST22. For example, the first bit line BL1 may be electrically coupled to the cell strings ST11 and ST21. In addition, the second bit line BL2 may be electrically coupled to the cell strings ST12 and ST22.

The source line SL may be commonly coupled to the cell strings ST11, ST12, ST21, and ST22. The source line SL may be coupled to a middle end of the cell strings ST11, ST12, ST21, and ST22. The cell strings ST11, ST12, ST21, and ST22 may connect the first and second bit lines BL1 and BL2 to the source line SL.

Each of the first and second common back gate lines CBGL1 and CBGL2 may extend in the Y direction. The first and second common back gate lines CBGL1 and CBGL2 may be coupled to the other end of the cell strings ST11, ST12, ST21, and ST22. For example, the first common back gate line CBGL1 may be electrically coupled to the cell strings ST11 and ST12. In addition, the second common back gate line CBGL2 may be electrically coupled to the cell strings ST21 and ST22.

Gates of the source select transistors SST11, SST12, SST21, and SST22 included in the different cell strings ST11, ST12, ST21, and ST22 may be commonly coupled to the source select line SSL. For example, the gates of the source select transistors SST11, SST12, SST21, and SST22 included in the cell strings ST11, ST12, ST21, and ST22 may be coupled connected to the source select line SSL.

Gates of memory cells included in different cell strings ST11, ST12, ST21, and ST22 may be commonly coupled to the first to eighth word lines WL1 to WL8. Memory cells formed on the same layer among the memory cells included in different cell strings ST11, ST12, ST21, and ST22 may be commonly coupled to the same word line. For example, gates of memory cells MC112, MC122, MC212, and MC222 included in each of the cell strings ST11, ST12, ST21, and ST22 and located on the same layer may be commonly coupled to the second word line WL2. A group of memory cells included in different cell strings ST11, ST12, ST21, and ST22 and coupled to the same word line (e.g., one of the first to eighth word lines WL1 to WL8) may form a page. A program operation and a read operation may be performed in units of pages, and an erase operation may be performed in units of memory blocks.

Gates of the drain select transistors DST11, DST12, DST21, and DST22 included in the cell strings ST11, ST12, ST21, and ST22 may be coupled to the drain select line DSL1 or DSL2. The drain select transistors (e.g., the drain select transistors DST11 and DST12) included in the cell strings (e.g., the cell strings ST11 and ST12) arranged in the Y direction among the cell strings ST11, ST12, ST21, and ST22 may be coupled to the same drain select line (e.g., the drain select line DSL1). For example, the gates of the drain select transistors DST11 and DST12 of the cell strings ST11 and ST12 may be commonly coupled to the first drain select line DSL1. In addition, the gates of the drain select transistors DST21 and DST22 of the cell strings ST21 and ST22 may be commonly coupled to the second drain select line DSL2.

Channel back gate lines BGL11, BGL12, BGL21, and BGL22 included in the cell strings ST11, ST12, ST21, and ST22 may be coupled to the common back gate line CBGL1 or CBGL2. The channel back gate lines BGL11 and BGL12 included in the cell strings ST11, ST12, ST21, and ST22 arranged in the Y direction (e.g., the cell strings ST11 and ST12) may be coupled to the same common back gate line (e.g., the common back gate line CBGL). For example, the channel back gate lines BGL11 and BGL12 of the cell strings ST11 and ST12 may be commonly coupled to the first common back gate line CBGL1. In addition, the channel back gate lines BGL21 and BGL22 of the cell strings ST21 and ST22 may be commonly coupled to the second common back gate line CBGL2.

According to an embodiment of the present disclosure, program performance may be improved compared to before by applying a separate back voltage Vb to the channel back gate line (e.g., the channel back gate line BGL11) when programming memory cells (e.g., the memory cell MC112). For example, when the cell to be programmed is the memory cell MC112, the second word line WL2 may be referred to as a selected word line, and the remaining word lines other than the second word lines WL2 may also be referred to as unselected word lines. The unselected word lines may be the first word line WL1 and the third to eighth word lines WL3 to WL8. The program voltage described with reference to FIG. 1 may be applied to the second word line WL2, which is the selected word line. The pass voltages described with reference to FIG. 1 may be applied to the first word line WL1 and the third to eighth word lines WL3 to WL8, which are the unselected word lines. Table 1 illustrates examples of voltages applied to the bit lines BL1 and BL2, the drain select lines DSL1 and DSL2, and the common back gate lines CBGL1 and CBGL2 when the memory cell MC112 is selected to be programmed.

TABLE 1

| | MC112 | | | |
|---|---|---|---|---|
| | (Cell to be | | | |
| | Programmed) | MC212 | MC122 | MC222 |
| BL | BL1: 0 V | BL1: 0 V | BL2: 2 V | BL2: 2 V |
| DSL | DSL1: 2 V | DSL2: 0 V | DSL1: 2 V | DSL2: 0 V |
| CBGL | CBGL1: −2 V | CBGL2: 2 V | CBGL1: −2 V | CBGL2: 2 V |

Referring to Table 1, a voltage having a first bit line level may be applied to the first bit line BL1 coupled to the cell string ST11 including the memory cell MC112 to be programmed. In addition, a voltage having a second bit line level different from the first bit line level may be applied to the second bit line BL2 which is not coupled to the cell string ST11 including the memory cell MC112 to be programmed. The first bit line level may be smaller than the second bit line level. For example, the first bit line level may be 0 V and the second bit line level may be 2 V.

The turn-on voltage described with reference to FIG. 1 may be applied to the first drain select line DSL1 coupled to the cell string ST11 including the memory cell MC112 to be programmed, and the turn-off voltage described with reference to FIG. 1 may be applied to the second drain select line DSR2 which is not coupled to the cell string ST11. The level of the turn-on voltage may be greater than the level of the turn-off voltage. For example, the turn-on voltage may be 2 V and the turn-off voltage may be 0 V.

A first back voltage may be applied to the first common back gate line CBGL1 coupled to the cell string ST11 including the memory cell MC112 to be programmed. In addition, a second back voltage may be applied to the second common back gate line CBGL2 that is not coupled to the cell string ST11 including the memory cell MC112 which is a cell to be programmed. The first back voltage may be smaller than 0 V and the second back voltage may be greater than 0 V. For example, the first back voltage may be −2 V and the second back voltage may be 2 V.

According to an embodiment of the present disclosure, because a negative bias is applied to the channel back gate line BGL11 of the memory cell MC112, which is a cell to be programmed, the speed at which the memory cell MC112 is programmed may increase. For example, the level of the program voltage required to program the memory cell MC112 may be reduced as the channel potential of the memory cell MC112 is reduced by the channel back gate line BGL11 to which the negative bias is applied.

In addition, in an embodiment, because a positive bias is applied to the channel back gate lines BGL21 and BGL22, interference by the memory cells MC212 and MC222 may be reduced when the memory cell MC112 is programmed. For example, interference with the memory cell MC112, which is a cell to be programmed, may be reduced as the channel potential of the memory cells MC212 and MC222 is increased by the channel back gate lines BGL21 and BGL22 to which the positive bias is applied.

In addition, in an embodiment, the off characteristics of the drain select transistor DST12 included in the cell string ST12 may be improved because a negative bias is applied to the channel back gate line BGL12. In an embodiment, the channel boosting level of the memory cell MC122 may be increased by improving the performance of the drain select transistor DST12. Therefore, in an embodiment, interference by the memory cell MC122 may be reduced when the memory cell MC112 is programmed.

Referring to FIGS. 4A and 4B, the channel boosting level of the memory cells included in the cell strings ST11, ST12, ST21, and ST22 may vary depending on the thickness of the liner layers LL included in the cell plugs CPL11, CPL12, CPL21, and CPL22. For example, the channel boosting level may decrease as the thickness of the liner layer LL decreases.

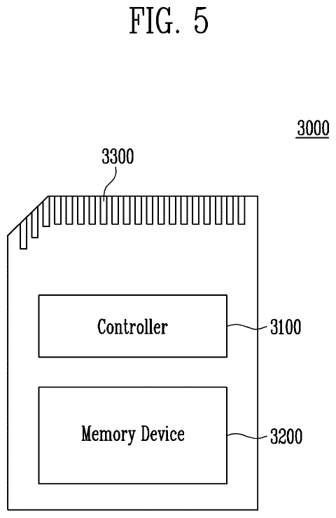

FIG. 5 is a diagram illustrating a memory card system 3000 to which a memory device according to an embodiment of the present disclosure is applied.

Referring to FIG. 5, the memory card system 3000 may include a controller 3100, a memory device 3200, and a connector 3300.

The controller 3100 may be coupled to the memory device 3200. The controller 3100 may be configured to access the memory device 3200. For example, the controller 3100 may be configured to control a program operation, a read operation, or an erase operation of the memory device 3200, or control a background operation. The controller 3100 may be configured to provide an interface between the memory device 3200 and a host. The controller 3100 may be configured to drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may be integrated into a single semiconductor device to constitute a memory card such as a personal computer (PC) card in the form of a Personal Computer Memory Card International Association (PCMCIA) card, a Compact Flash (CF) card, a Smart Media Card (SM and SMC), a memory stick, a Multi-Media Card (MMC, RS-MMC, MMCmicro, or eMMC), a Secure Digital (SD) card (SD, miniSD, microSD, or SDHC), and a Universal Flash Storage (UFS).

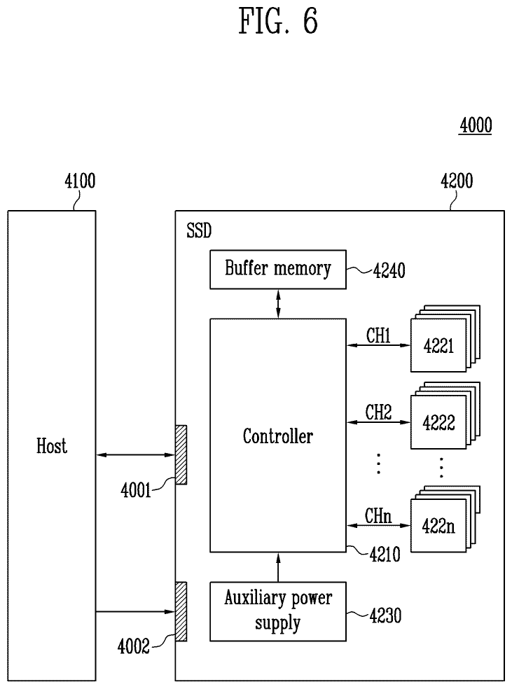

FIG. 6 is a diagram illustrating a solid state drive (SSD) system 4000 to which a memory device according to an embodiment of the present disclosure is applied.

Referring to FIG. 6, the SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to signals received from the host 4100. For example, the signals may be based on an interface between the host 4100 and the SSD 4200. For example, the signals may be defined by at least one of interfaces such as Universal Serial Bus (USB), Multi-Media Card (MMC), embedded MMC (eMMC), Peripheral Component Interconnect (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe interfaces.

The plurality of memory devices 4221 to 422n may include a plurality of memory cells configured to store data. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive and be charged with a power voltage from the host 4100. When the supply of power from the host 4100 is not smooth, the auxiliary power supply 4230 may provide a power voltage of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to various embodiments of the present disclosure, the performance of program operations may be enhanced by improving the structure of memory cells.

What is claimed is:

1. A memory device, comprising:
a stack structure including conductive layers and interlayer insulating layers;
a channel layer penetrating the stack structure;
a channel back gate layer surrounded by the channel layer; and
a liner layer insulating the channel layer and the channel back gate layer from each other,
wherein the channel layer and the channel back gate layer have different electrical paths from each other.

2. The memory device of claim 1, further comprising:
a source layer located over the stack structure; and
a common back gate layer located over the source layer.

3. The memory device of claim 2, wherein the channel back gate layer penetrates the source layer to contact the common back gate layer.

4. The memory device of claim 2, wherein the channel back gate layer protrudes toward the common back gate layer further than the channel layer in the stacking direction of the conductive layers and interlayer insulating layers.

5. The memory device of claim 2,
wherein a vertical direction is the stacking direction of the conductive layers and interlayer insulating layers,
wherein the channel back gate layer extends in the vertical direction, and
wherein the common back gate layer extends in a horizontal direction crossing the vertical direction.

6. The memory device of claim 2, wherein the liner layer extends between the channel back gate layer and the channel layer, between the channel back gate layer and the source layer, and between the common back gate layer and the source layer.

7. The memory device of claim 6, wherein the channel back gate layer and the common back gate layer are insulated from the channel layer and the source layer by the liner layer.

8. The memory device of claim 2, wherein the channel back gate layer and the common back gate layer are integrally formed.

9. The memory device of claim 2, wherein each of the channel back gate layer and the common back gate layer includes at least one of polysilicon or metal.

10. The memory device of claim 1,
wherein the channel back gate layer has substantially a cylindrical shape extending in a first direction, and
wherein the channel layer has substantially a cylindrical shape surrounding the channel back gate layer and the liner layer and extending in the first direction.

11. The memory device of claim 1, further comprising a memory layer surrounding the channel back gate layer, the liner layer, and the channel layer.

12. The memory device of claim 1, wherein the channel back gate layer is insulated from the conductive layers.

13. The memory device of claim 1, wherein the channel layer includes a doping region.

14. The memory device of claim 13, wherein the doping region horizontally overlaps with an uppermost conductive layer and a second conductive layer from the top of the stack structure.

15. A memory device, comprising:
a stack structure including conductive layers and interlayer insulating layers; and
cell plugs penetrating the stack structure,
wherein each of the cell plugs includes:
a channel layer;
a channel back gate layer surrounded by the channel layer; and
a liner layer insulating the channel layer and the channel back gate layer from each other, and
wherein the channel layer and the channel back gate layer have different electrical paths from each other.

16. The memory device of claim 15, further comprising:
bit lines located in a first direction with respect to the stack structure; and
common back gate layers located in an opposite direction of the first direction with respect to the stack structure.

17. The memory device of claim 16,
wherein each of the bit lines extends in a second direction crossing the first direction, and
wherein each of the common back gate layers extends in a third direction crossing the first direction and the second direction.

18. The memory device of claim 17,
wherein the bit lines are spaced apart from each other in the third direction, and
wherein the common back gate layers are spaced apart from each other in the second direction.

19. The memory device of claim 17, wherein a first bit line among the bit lines is commonly coupled to the channel layer included in each of the cell plugs adjacent in the second direction among the cell plugs.

20. The memory device of claim 17, wherein a first back gate layer among the back gate layers is commonly coupled to the channel back gate layer included in each of the cell plugs adjacent in the third direction among the cell plugs.

21. The memory device of claim 17, wherein:
the conductive layers include select lines,
the select lines are spaced apart from each other in the second direction, and
each of the select lines extends in the third direction.

22. The memory device of claim 17, further comprising a source layer located between the stack structure and the common back gate layers.

23. The memory device of claim 22, wherein the source layer is commonly coupled to the channel layer included in each of the cell plugs adjacent in the second direction and the third direction among the cell plugs.

24. The memory device of claim 22, wherein:
the channel layer forms a first electrical path with at least one bit line among the bit lines and the source layer,
the channel back gate layer forms a second electrical path with at least one common back gate layer among the common back gate layers, and
the first electrical path and the second electrical path are insulated from each other.

25. The memory device of claim 24, wherein at least one conductive layer among the conductive layers forms a third electrical path, and
wherein the third electrical path is insulated from the first electrical path and the second electrical path.

26. The memory device of claim 22, wherein the liner layer extends between the channel layer and the channel back gate layer, between the source layer and the channel back gate layer, and between the source layer and the common back gate layers.

27. The memory device of claim 16,
wherein each of the cell plugs further includes a capping layer coupled to the channel layer between the channel back gate layer and the bit lines, and
wherein the liner layer extends between the channel back gate layer and the capping layer.

28. A memory device, comprising:
a stack structure including conductive layers and interlayer insulating layers;
a channel layer penetrating the stack structure;
a channel back gate layer surrounded by the channel layer; and
a liner layer insulating the channel layer and the channel back gate layer from each other,
wherein the channel layer is included in a first current path and the channel back gate layer is included in a second current path.

29. The memory device of claim 28, wherein the first current path is insulated from the second current path.

30. The memory device of claim 28,
wherein the first current path includes the channel layer coupled to a source layer located on the stack structure, and
wherein the second current path includes the channel back gate layer coupled to a common back gate layer located over the source layer.

31. The memory device of claim 28,
wherein the first current path is spaced apart from the second current path by a liner layer.

32. The memory device of claim 31,
wherein the liner layer includes an oxide.

33. The memory device of claim 28,
wherein the first current path is different from the second current path.

34. The memory device of claim 28,
wherein a liner layer is located between the first current path and the second current path.

35. The memory device of claim 28, wherein the channel layer includes a first material and the channel back gate layer includes a second material different from the first material.

36. The memory device of claim 35,
wherein the channel layer includes a silicon layer, and
wherein the channel back gate layer includes a polysilicon or metal.
